(19) United States
(12) Patent Application Publication
(10) Pub. No.: US 2018/0337082 A1
(43) Pub. Date: Nov. 22, 2018

(54) MIXED GROUP-V SACRIFICIAL LAYERS FOR RELEASE AND TRANSFER OF MEMBRANES

(71) Applicant: STC.UNM, Albuquerque, NM (US)

(72) Inventors: Sanjay KRISHNA, Albuquerque, NM (US); Brianna KLEIN, Albuquerque, NM (US); Francesca CAVALLO, Albuquerque, NM (US); Seyedeh Marziyeh ZAMIRI, Albuquerque, NM (US)

(21) Appl. No.: 15/755,860

(22) PCT Filed: Aug. 30, 2016
(86) PCT No.: PCT/US2016/049529

§ 371 Date: Feb. 27, 2018

Related U.S. Application Data
(60) Provisional application No. 62/212,413, filed on Aug. 31, 2015.
(60) Provisional application No. 62/213,040, filed on Sep. 1, 2015.

(51) Int. Cl. H01L 21/683; H01L 31/0352; H01L 31/0304; H01L 31/18; H01L 27/146

(52) U.S. Cl. CPC H01L 21/6835; H01L 31/035236; H01L 31/0304; H01L 31/184; H01L 2221/68381; H01L 27/14649; H01L 27/14694; H01L 27/14689; H01L 2221/68368; H01L 31/1892

(57) ABSTRACT

A method for forming a semiconductor structure, includes: providing a host substrate; forming at least one sacrificial layer having two or more group-V species over the host substrate; forming at least one semiconductor layer over the at least one sacrificial layer; and transferring at least a portion of the at least one semiconductor layer from the host substrate onto an alternate substrate.

### CROSS-REFERENCE TO RELATED APPLICATIONS

This application claims priority to U.S. Provisional Patent Application Ser. No. 62/212,413, filed Aug. 31, 2015, and to U.S. Provisional Patent Application Ser. No. 62/213,040, filed Sep. 1, 2015 the entireties of which are incorporated herein by reference.

### GOVERNMENT RIGHTS

This disclosure was made with Government support under Contract No. FA9550-10-1-0113 awarded by the Air Force Office of Scientific Research. The Government may have certain rights in the invention.

### TECHNICAL FIELD

Embodiments described herein relate generally to semiconductor manufacturing, specifically methods for transferring multilayer semiconductor structures from a host (e.g., growth) substrate to an alternate substrate.

### BACKGROUND

Compound semiconductors are used in a variety of electronic and photonic devices including light emitting diodes, lasers, detectors, solar cells, transistors and other diodes. Many compound semiconductors include Group III elements (e.g., Ga, Al, In etc) and group V elements (e.g., N, As, P, Sb etc). These III-V semiconductors include GaAs, GaP, InP, GaSb, InAs etc. Most III-V semiconductors are epitaxially grown on a substrate using advanced crystallographic or epitaxial techniques. There is interest to transfer these semiconductors onto alternate substrates that are cheaper, flexible, and easy to manufacture.

Meanwhile, epitaxially grown single-crystalline semiconductor nanomembranes (NMs) offer a new platform for fundamental science and advanced technology. Progress in NM fabrication has already significantly altered the landscape, as it relates to properties and applications of group IV and III-V semiconductors, III-nitrides and various oxide materials. Despite the numerous demonstrations of NM technology applied to III-V materials, fabrication and detailed characterization of Sb-based superlattices (SLs) in membrane form has not been reported.

For example, typically, type II superlattices (T2SLs) are epitaxially grown on GaSb substrates. While these substrates provide mechanical support during device fabrication, they are undesirable in IR cameras. GaSb substrates absorb much of the incoming radiation in the IR range, thus reducing the signal-to-noise ratio (SNR). In addition, T2SLs/GaSb substrates are bonded to a Si read-out circuit (ROIC) to realize infrared focal plane arrays (FPAs). As the detectors-ROIC combination is cryogenically cooled during operation, the large thermal mismatch between the GaSb substrate and the Si ROIC results in structural failure of the imaging device, via cracking of the absorber or delamination of the detectors from the ROIC. To overcome these issues, the GaSb substrate is routinely removed by chemical-mechanical polishing (CMP) and selective etching, thereby increasing manufacturing costs, and inducing damages in either the detectors or the ROIC.

What is needed, therefore, is a method for removing semiconductor structures from their growth substrates and transferring them onto alternate substrates and overcomes the limitations of conventional methods.

### SUMMARY

In an embodiment there is a method for forming a semiconductor structure, comprising: providing a host substrate; forming at least one sacrificial layer comprising two or more group-V species over the host substrate; forming at least one semiconductor layer over the at least one sacrificial layer; and transferring at least a portion of the at least one semiconductor layer from the host substrate onto an alternate substrate.

In another embodiment, there is a method for forming a semiconductor structure, comprising: providing a host substrate; forming at least one sacrificial layer over the host substrate; forming at least one semiconductor layer over the at least one sacrificial layer; patterning the at least one semiconductor layer to expose sidewall portions of the semiconductor layer; forming a protective layer over at least the exposed sidewall portions of the at least one semiconductor layer; selectively etching the at least one sacrificial layer; and transferring at least a portion of the at least one semiconductor layer from the host substrate onto an alternate substrate.

Benefits of the disclosed processes for forming semiconductor superlattice structures include the ability to release and transfer without degrading the crystalline quality of the films. Further, the disclosed processes open the possibility to engineer strain distributions, which are not obtainable within the limitations of epitaxial growth processes. For example, a superlattice will undergo elastic deformation during a release portion of the transfer process, thereby resulting in the redistributing of strain intrinsic to the deposition process between the different layers in the SL. Furthermore, superlattices may be bonded and conformed to patterned surfaces of various shapes and sizes to induce local strain of different types and amplitudes. As strain modifies electronic band structure, electronic transport, optoelectronic properties, and phonon structure, it may be harnessed to obtain unique characteristics not present in the relaxed material.

Additionally, Transfer of Sb-based type-II superlattices (T2SLs) onto insulating materials, as provided by the methods described herein, enable investigation of electrical transport in the heterostructure via Hall and van Der Pauw measurements, which are not applicable to T2SLs supported by GaSb substrates.

Additional advantages of the embodiments will be set forth in part in the description which follows, and in part will be understood from the description, or may be learned by practice of the embodiments. The advantages will be realized and attained by means of the elements and combinations particularly pointed out in the appended claims.

It is to be understood that both the foregoing general description and the following detailed description are exemplary and explanatory only and are not restrictive of the embodiments, as claimed.

### BRIEF DESCRIPTION OF THE DRAWINGS

The accompanying drawings, which are incorporated in and constitute a part of this specification, illustrate embodiments of the present teachings and together with the description, serve to explain the principles of the disclosure.

FIGS. 1A-1D illustrate various stages of a method for the release and wet transfer of active region from a host substrate to an alternate substrate according to an embodiment.

FIGS. 2A-2E illustrate various stages of a method for the release and dry transfer of an active region from a host substrate to an alternate substrate according to an embodiment.

FIG. 3A is a flow chart representative of the method illustrated in FIGS. 1A-1D.

FIG. 3B is a flow chart representative of the method illustrated in FIGS. 2A-2E.

FIGS. 4A-4E illustrate various stages of a method for the release and wet transfer of an active region from a host substrate to an alternate substrate according to an embodiment.

FIGS. 5A-5G illustrate various stages of a method for the release and dry transfer of an active region from a host substrate to an alternate substrate according to an embodiment.

FIG. 6A is a flow chart representative of the method illustrated in FIGS. 4A-4E.

FIG. 6B is a flow chart representative of the method illustrated in FIGS. 5A-5G.

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the embodiments are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g., −1, −2, −3, −10, −20, −30, etc.

The following embodiments are described for illustrative purposes only with reference to the figures. Those of skill in the art will appreciate that the following description is exemplary in nature, and that various modifications to the parameters set forth herein could be made without departing from the scope of the present embodiments. It is intended that the specification and examples be considered as examples only. The various embodiments are not necessarily mutually exclusive, as some embodiments can be combined with one or more other embodiments to form new embodiments. It will be understood that the structures depicted in the figures may include additional features not depicted for simplicity, while depicted structures may be removed or modified.

There are several approaches by which one or more layers of a semiconductor structure can be transferred from a host substrate (e.g., a growth substrate (GS)) and onto an alternate substrate (AS). In one approach, one or more layers of the compound semiconductor are grown over a sacrificial layer (SL) disposed on a host substrate. The compound semiconductor can then be partially or fully separated (e.g., released) from the growth substrate. The separation is achieved by selective removal the SL via a dry or wet etching process.

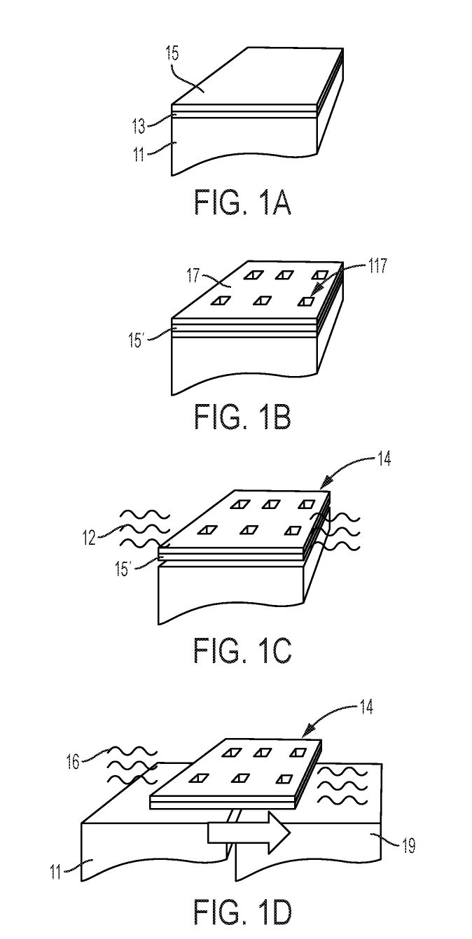

For example, FIGS. 1A-1D illustrate various steps of a method for forming a semiconductor structure. The method includes removing at least one semiconductor layer from a host substrate and transferring it to an alternate substrate. As shown in FIG. 1A, an initial stack comprises a host substrate 11, at least one sacrificial layer 13 disposed on the host substrate 11, and an active region 15 comprising at least one semiconductor layer disposed on the sacrificial layer 13. The active region may then patterned to comprise a 2D array of holes (not shown) via, for example, inductively coupled plasma (ICP) etching. The forming of the holes exposes additional surface area of the active region 15, such as sidewall portions thereof that define the perimeter of the holes. The holes also expose the underlying sacrificial layer 13 to the ambient environment and provide access for an etchant to etch the sacrificial layer in a subsequent etching step. Meanwhile, as shown in FIG. 1B, a protective layer 17 can be formed over the active region. For example, the protective layer 17 can be formed over patterned active region 15′ at 117 to protect a top surface of the active region and/or to protect the sidewall portions of the patterned active region, such as the sidewall portions of the active region that define the perimeter of the holes. The protective layer 17 may also be formed on a top surface of the active region 15. For example, a top surface of the patterned active region 15′. In an embodiment, the protective layer 17 may be formed to at least partially or fully encapsulate the active region 15. For example, the protective layer 17 may be formed to at least partially encapsulate or fully encapsulate active region 15 after it is patterned into patterned active region 15′. Alternatively, the protective layer may be formed over the active region either as a blanket layer that is subsequently patterned or in a predetermined pattern. Then the pattern of the protective layer may be transferred to the underlying active region and to the sacrificial layer, for example, via etching.

The sacrificial layer 13 may, therefore, be partially or fully removed by selective etching thereof, using dry etching, wet etching, vapor etching or a combination thereof without the etchant causing any damage to the active region. In an example, the sacrificial layer 13 is exposed to wet etchant solution 12 which selectively etches away the sacrificial layer as shown in FIG. 1C, but does not etch the active region 15. In an example, the wet etchant can comprise diluted hydrogen fluoride (HF) (e.g., [(HF:H2O) 1:700]:ethanol 1:5).

Upon complete removal of the sacrificial layer 13, the patterned active region 15′ may be partially or completely released from the host substrate 11. The partially or completely released patterned active region 15′ may then be transferred to alternate substrate 19. Upon removal of the sacrificial layer 13 an upper surface and a lower surface of the patterned active region 15′ may each have an RMS roughness value of from about lnm to about 2 nm. In other words, sacrificial layer 13 may be considered sufficiently removed from a surface of the active region when the RMS roughness value of the surface that was in contact with the sacrificial layer is about that of an upper surface of the active region.

In the case of complete removal of the sacrificial layer 13, the patterned active region 15′ may bond-back to the host substrate. Accordingly, after etching of the sacrificial layer 13, to facilitate release of the patterned active region 15′ from the substrate 11, patterned active region 15′ and the underlying host substrate 11 may be immersed in a liquid 16 such as water. In the liquid 16, the patterned active region 15′ can free-float and prevent bonding back to the host substrate. The alternate substrate 19 may also be immersed in the liquid 16 to accept the free-floating patterned active region 15′ onto a surface thereof as shown in FIG. 1D. Accordingly, in the case of a complete release of the patterned active region 15′ from the substrate 11, the active layer may be directly transferred to the alternate substrate 19.

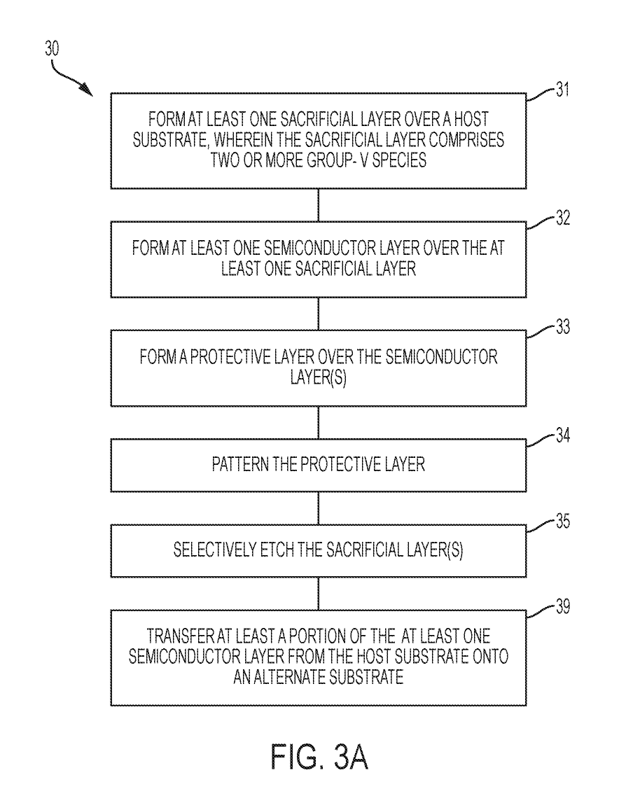

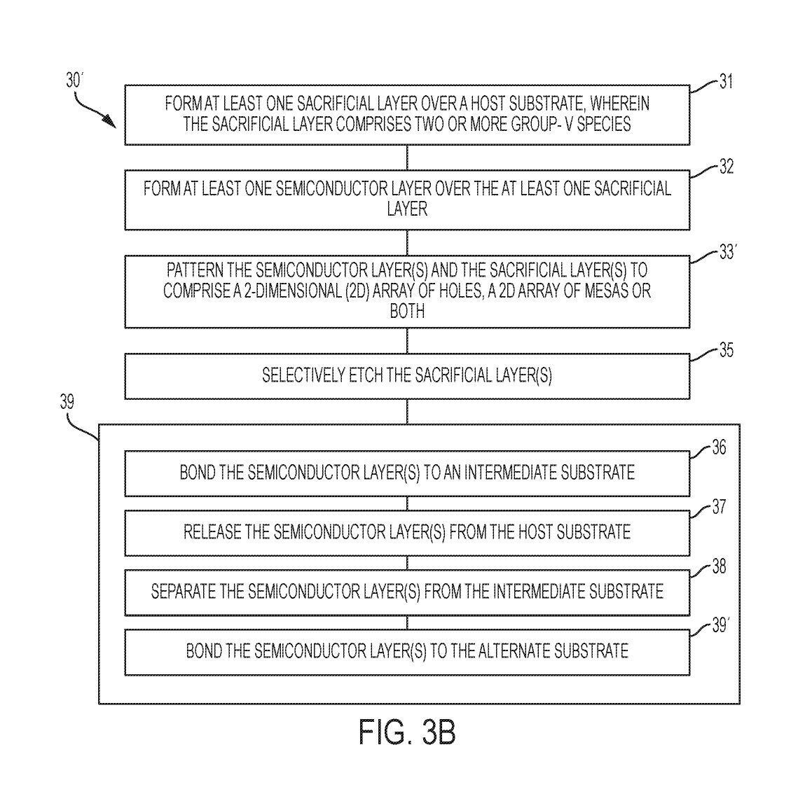

The steps outlined above for FIGS. 1A-1D may be implemented in a method for forming a semiconductor structure as outlined in the flowchart 30 in FIG. 3A. In general, the method includes providing the host substrate and forming at least one sacrificial layer comprising two or more group-V species over the host substrate at step 31. The active region, which may comprise at least one semiconductor layer, may be formed over the at least one sacrificial layer at step 32. The protective layer may be formed over the active region (i.e., over the at least one sacrificial layer) at step 33, for example, in a predetermined pattern. The active region, the protective layer or both may be patterned (e.g., etched) at 34 and selective etching of the sacrificial layer(s) at step 35. For example, the protective layer may be formed over the active region either as a blanket layer that is subsequently patterned or in a predetermined pattern. Then the pattern of the protective layer may be transferred to the active region and to the sacrificial layer, for example, via etching. As described above, at least a portion of the active region's semiconductor layer(s) may then be transferred from the host substrate onto an alternate substrate at step 39.

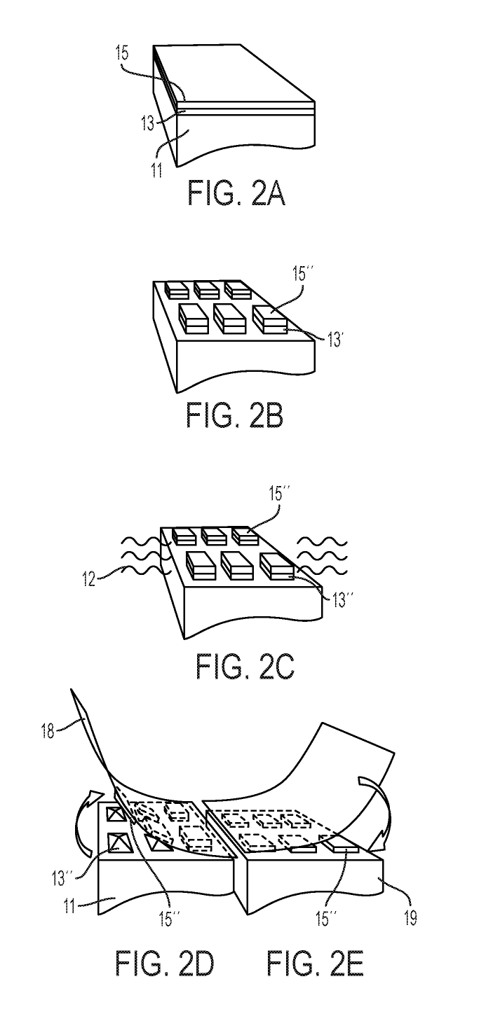

Returning to FIGS. 2A-2E, various steps of another method for removing and transferring at least one semiconductor layer from a host substrate to an alternate substrate are depicted. Similar to FIG. 1A, an initial stack in FIG. 2A comprises the host substrate 11, the at least one sacrificial layer 13 disposed on the host substrate 11, and the active region 15 disposed on the sacrificial layer 13. At this stage, the active region 15 may be patterned to form a patterned active region 15″ comprising, for example, a 2D array of mesas as shown in FIG. 2B. Likewise, the sacrificial layer 13 underlying the active region 15 may also be patterned to form a patterned sacrificial layer 13′ comprising, for example, a 2D array of mesas underlying the mesas of patterned active region 15″. The mesas of the patterned active region 15″ and of the patterned sacrificial layer 13′ effectively increase the available surface area by exposing sidewall portions of the active region 15 and of the sacrificial layer 13 to the ambient environment. Accordingly, the sidewall portions increase the effectiveness of an etchant when it is exposed to the sacrificial layer in a subsequent step.

The patterned sacrificial layer 13′ may be partially or fully removed by selective etching thereof, using dry etching, wet etching, vapor etching or a combination thereof. In an example, the patterned sacrificial layer 13′ is exposed to wet etchant solution 12 which selectively etches away the sacrificial layer as shown in FIG. 1C, but does not substantially etch the active region 15 due, in part, to the etchant selectivity. In an example, the wet etchant can comprise diluted hydrogen fluoride (HF) (e.g., [(HF:H2O) 1:700]:ethanol 1:5). In FIG. 2C, the wet etchant is shown to have partially etched the sacrificial layer resulting in some amount of weakened sacrificial layer 13″ on the substrate. As shown in FIG. 2D, an intermediate substrate 18 may then be stamped onto the plurality of patterned active region 15″ mesas, resulting in a bonding between the active region material and the intermediate substrate. As the intermediate substrate is pulled away, the patterned active region 15″ mesas are separated from the substrate 11 and the weakened sacrificial layer 13″. The intermediate substrate with active region 15″ mesas bonded to a surface thereof may then be used as a stamp by pressing it against a surface of an alternate substrate 19. Upon stamping the patterned active region 15″ mesas are transferred to the alternate substrate 17 surface as shown in FIG. 2E. Accordingly, in the case of a partial release of the mesas of patterned active region 15″ from the substrate 11, the active region material is indirectly transferred to the alternate substrate 19 via a stamp-like intermediate substrate 18.

The steps outlined above for FIGS. 2A-2E may be implemented in a method for forming a semiconductor structure as outlined in the flowchart 30′ in FIG. 3B. In general, the method 30′ includes providing the host substrate and forming at least one sacrificial layer comprising two or more group-V species over the host substrate at step 31. The active region, which may comprise at least one semiconductor layer, may be formed over the at least one sacrificial layer at step 32. The semiconductor layer(s) of the active region and the sacrificial layer(s) may be patterned to comprise a 2D array of holes, mesas or both at step 33′ followed by selective etching of the sacrificial layer(s) at step 35. As described above, at least a portion of the active region's semiconductor layer(s) may then be transferred from the host substrate onto an alternate substrate at step 39. However, here, step 39 comprises the sub-steps of bonding the semiconductor layer(s) of the active region to an intermediate substrate at step 36 followed by releasing of the active region from the host substrate at step 37. The active region may then be separated from the intermediate substrate at step 38, for example, after stamping the transferred active region semiconductor layer(s) onto the alternate substrate. For example, the active region semiconductor layer(s) may be bonded to the alternate substrate at step 39′.

In another embodiment, there is a process that provides for the release and transfer of semiconductor layers, such as III-V semiconductor layers on any substrate, for example, semiconductor layers that comprise Al and Ga. The process utilizes two etching steps. In an example, a first etch step provides for the etching to a first etch depth while a second etch step provides for the etching to a second etch depth.

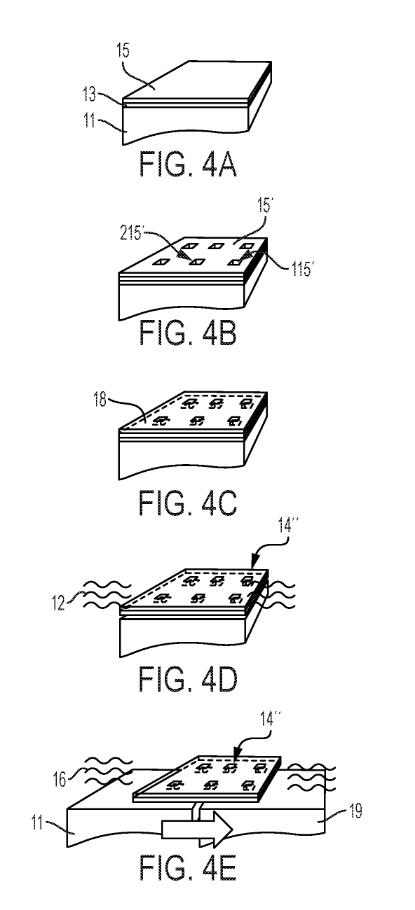

As illustrated to FIGS. 4A-4E, various steps of a method for removing and transferring at least one semiconductor layer from a host substrate to an alternate substrate are depicted. Similar to FIGS. 1A and 2A, an initial stack in FIG. 4A comprises the host substrate 11, the at least one sacrificial layer 13 disposed on the host substrate 11, and the active region 15 disposed on the sacrificial layer 13. As shown in FIG. 4B, the active region 15 may be patterned to form a patterned active region 15′ comprising, for example, a 2D array of holes 115′. The holes 115′ expose additional surface area of the active region, for example, at sidewall portions 215′ of the patterned active region 15′.

The patterning of the active region 15 may be accomplished by etching via ICP, for example, through a thickness of the active region 15 and terminating the etching at the sacrificial layer 13 (i.e., without etching the sacrificial layer). The patterning, therefore, results in exposing of underlying surface portions of the sacrificial layer 13 such that an etchant can later reach the sacrificial layer during a subsequent, second etching step.

Protective layer 17, which may be a photoresist, may be formed to at least partially or fully encapsulate the active region 15. For example, the protective layer 17 may be formed to at least partially encapsulate or fully encapsulate active region 15 after it is patterned into patterned active region 15′. That is, in an embodiment, the protective layer may be deposited on the patterned active region 15′ as shown in FIG. 4C. For example, the protective layer 17 may be formed over at least the sidewalls 115′, and may be deposited over an upper surface of the patterned active region 15′. The protective layer 17 may be formed in such a pattern that it does not cover the portions of the underlying sacrificial layer 13 previously exposed during the first etch of the active region 15. Accordingly, the sacrificial layer may be etched to remove preliminary portions thereof, leaving a patterned sacrificial layer (not shown).

In an example as shown in FIG. 4D, the sacrificial layer 13 may then be exposed to wet etchant solution 12 which selectively etches away the remaining portions of sacrificial layer 13, but does not etch the patterned active region 15′. The selective etching may be performed in diluted HF solution (e.g., [(HF:H2O) 1:700]:ethanol 1:5).

As with the stages illustrated in FIGS. 1A-1D and described above, upon complete removal of the sacrificial layer 13 as shown in FIG. 4D, the patterned active region 15′ may be partially or completely released from the host substrate 11. The partially or completely released patterned active region 15′ may then be transferred to alternate substrate 19. In the case of complete removal of the sacrificial layer 13, the patterned active region 15′ may bond-back to the host substrate. Accordingly, after etching of the sacrificial layer 13, to facilitate release of the patterned active region 15′ from the substrate 11, patterned active region 15′ and the underlying host substrate 11 may be immersed in a liquid 16 such as water. In the liquid 16, the patterned active region 15′ can free-float and prevent bonding back to the host substrate. The alternate substrate 19 may also be immersed in the liquid 16 to accept the free-floating patterned active region 15′ onto a surface thereof as shown in FIG. 4E. Accordingly, in the case of a complete release of the patterned active region 15′ from the substrate 11, the active layer may be directly transferred to the alternate substrate 19.

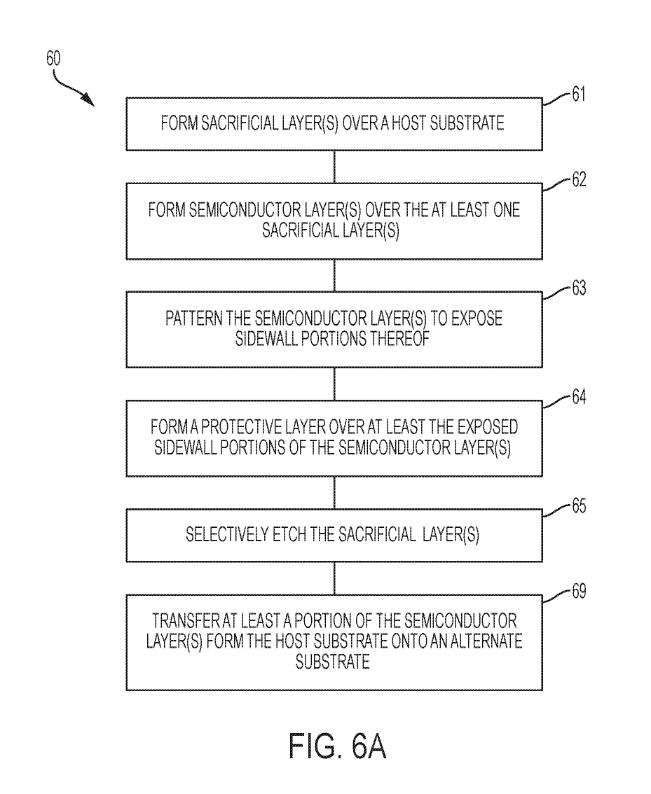

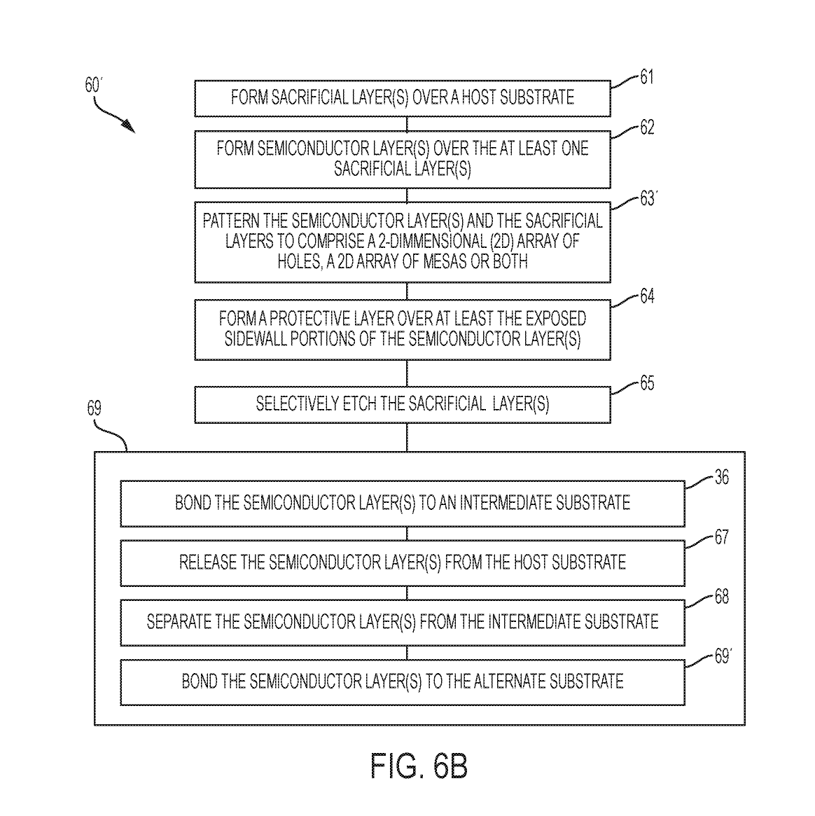

The steps outlined above for FIGS. 4A-4E may be implemented in a method for forming a semiconductor structure as outlined in the flowchart 60 in FIG. 6A. In general, the method includes providing the host substrate and forming at least one sacrificial layer over the host substrate at step 61. The active region, which may comprise at least one semiconductor layer, may be formed over the at least one sacrificial layer at step 62. The active region comprising the semiconductor layer(s) may be patterned at step 63 and the protective layer may be formed over the active region at step 64. The sacrificial layer(s) may then be selectively etched at step 65. As described above, at least a portion of the active region's semiconductor layer(s) may then be transferred from the host substrate onto an alternate substrate at step 69.

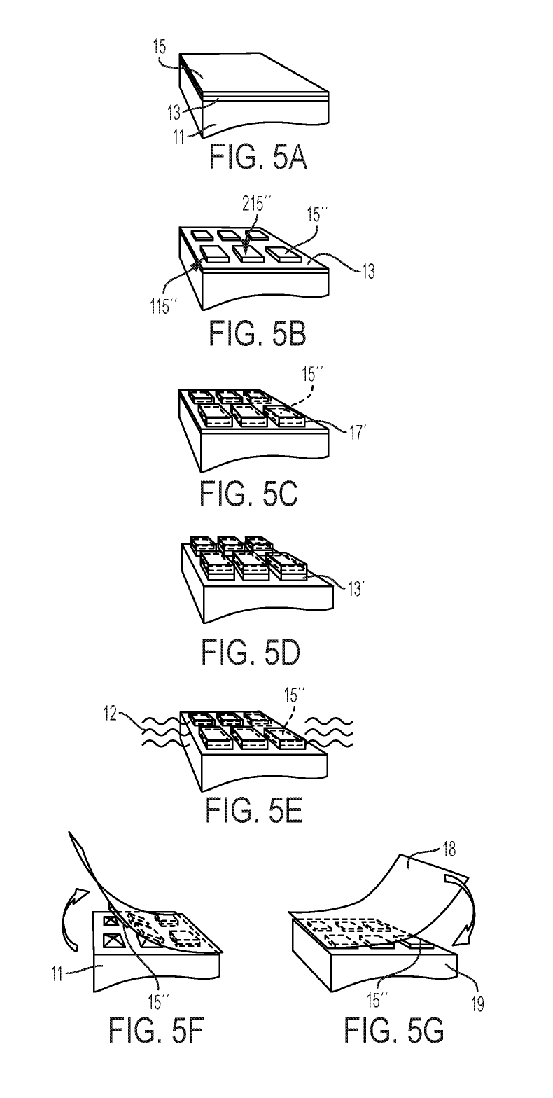

Returning to FIGS. 5A-5G, various steps of another method for removing and transferring at least one semiconductor layer from a host substrate to an alternate substrate are depicted. Similar to FIGS. 1A, 2A and 4A an initial stack in FIG. 5A comprises the host substrate 11, the at least one sacrificial layer 13 disposed on the host substrate 11, and the active region 15 disposed on the sacrificial layer 13. The active region 15 may be patterned to form a patterned active region 15″ comprising, for example, a 2D array of mesas as shown in FIG. 5B. The patterning of the active region exposes additional surface area, such as sidewall portions 115″. The patterning may be performed by ICP etching. This etch may be performed only on the active region such that it does not etch the sacrificial layer. As shown in FIG. 5C, a protective layer may be formed to at least partially or fully encapsulate the active region. For example, a protective layer may be formed to at least partially encapsulate or fully encapsulate active region 15 after it is patterned into patterned active region 15″. That is, in an embodiment, a protective layer 17′ may be formed over the patterned active region 15″ in order to protect the mesas during subsequent patterning of the sacrificial layer shown in FIG. 5D to form the patterned sacrificial layer 13. The mesas of the patterned active region 15″ and of the patterned sacrificial layer 13′ effectively increase the available surface area by exposing sidewall portions of the active region 15 and of the sacrificial layer 13 to the ambient environment. Accordingly, the sidewall portions increase the effectiveness of an etchant when it is exposed to the sacrificial layer in a subsequent step.

The patterned sacrificial layer 13′ may be partially or fully removed by selective etching thereof, using dry etching, wet etching, vapor etching or a combination thereof. In an example, the patterned sacrificial layer 13′ is exposed to wet etchant solution 12 which selectively etches away the sacrificial layer as shown in FIG. 5E, but does not substantially etch the active region 15 due, in part, to the etchant selectivity but also because of the protective layer coating the mesas. In an example, the wet etchant can comprise diluted hydrogen fluoride (HF) (e.g., [(HF:H2O) 1:700]:ethanol 1:5).

The wet etchant may partially etch, and weaken the attachment between the patterned sacrificial layer and the mesas. As shown in FIG. 5F, an intermediate substrate 18 may then be stamped onto the plurality of patterned active region 15″ mesas, resulting in a bonding between the active region material and the intermediate substrate. As the intermediate substrate is pulled away, the patterned active region 15″ mesas are separated from the substrate 11 and the weakened sacrificial layer. The intermediate substrate with active region 15″ mesas bonded to a surface thereof may then be used as a stamp by pressing it against a surface of an alternate substrate 19. Upon stamping the patterned active region 15″ mesas are transferred to the alternate substrate 17 surface as shown in FIG. 5G. Accordingly, in the case of a partial release of the patterned active region 15″ mesas from the substrate 11, the active region material is indirectly transferred to the alternate substrate 19 via a stamp-like intermediate substrate 18. The protective layer 17′ can be removed in a subsequent step in order to expose the transferred active region 15″.

The steps outlined above for FIGS. 5A-5G may be implemented in a method for forming a semiconductor structure as outlined in the flowchart 60′ in FIG. 6B. In general, the method 30′ includes providing the host substrate and forming at least one sacrificial layer comprising two or more group-V species over the host substrate at step 61. The active region, which may comprise at least one semiconductor layer, may be formed over the at least one sacrificial layer at step 62. The semiconductor layer(s) of the active region and the sacrificial layer(s) may be patterned to comprise a 2D array of holes, mesas or both at step 63′ followed by forming of a protective layer over at least the exposed sidewall portions of the active region's semiconductor layer(s) at step 64, although the protective layer may be formed to completely cover all exposed surface of the patterned active region. Next, at step 65, the sacrificial layer(s) are selectively etched. As described above, at least a portion of the active region's semiconductor layer(s) may then be transferred from the host substrate onto an alternate substrate at step 69. However, here, step 69 comprises the sub-steps of bonding the semiconductor layer(s) of the active region to an intermediate substrate at step 66 followed by releasing of the active region from the host substrate at step 67. The active region may then be separated from the intermediate substrate at step 68, for example, after stamping the transferred active region semiconductor layer(s) onto the alternate substrate. For example, the active region semiconductor layer(s) may be bonded to the alternate substrate at step 69′.

Practice of the embodiments illustrated in FIGS. 4A-4E, 5A-5G, and 6-7 overcome the challenges associated with some III-V active region systems, for example, the III-N system where conventional methods resort to the use of photochemical etching. Where conventional methods rely on aluminum and aluminum-containing compounds etch faster than the overlying compound semiconductors of the active region—thereby precluding inclusion of aluminum in the active region—the two-step etch process described herein allows for selective etching thereof and opens the possibility for transferring undamaged active regions comprising compound semiconductors that include aluminum. Additionally, the semiconductor structures made according to the embodiments described above and illustrated in FIGS. 4A-4E, 5A5, and 6A-6B may be used for various purposes, including for electronic or photonic devices. For example, complicated heterostructures can be transferred to a silicon wafer and the host substrate may be recycled after transfer of the active region grown thereon.

Practice of the embodiments, for example, those illustrated in FIGS. 4A-4E, 5A-5G, and 6A-6B, overcome the challenges associated with inclusion of aluminum in the active region, such as those grown on a host substrate. For example, where aluminum otherwise etches at a faster rate than the compound semiconductors of the active region, a mixed-group V sacrificial layer allows for a sacrificial layer which is lattice matched to the host substrate. In turn, this for a thicker sacrificial layer, or up to a 100% Al containing sacrificial layer which expedites the sacrificial etch process. Additionally, the semiconductor structures made according to the embodiments described above and illustrated in, for example, FIGS. 1A-1D, 2A-2E, 3A-3B, 4A-4E, 5A-5G, and 6A-6B may be used for various purposes, including for electronic or photonic devices. For example, complicated heterostructures can be transferred to a silicon wafer and the host substrate may be recycled after transfer of the active region grown thereon.

Any suitable substrate may be used for host substrate 11. The host substrate may be the substrate on which a semiconductor structure can be epitaxially grown thereon. That is, the host substrate may comprise a growth substrate. In at least one example, the host substrate may comprise a conducting substrate. Exemplary host substrates may comprise GaAs, GaSb, InP, InAs, InSb, or combinations thereof.

The sacrificial layer may be selected so as to be lattice matched to the underlying host substrate. The sacrificial layer may comprise at least one group-III material and at least one group-V material. Accordingly, the sacrificial layer may comprise at least one of In, Ga, Al, and at least one of N, As, P, Sb, Bi.

The sacrificial layer may comprise a mixed group-V sacrificial layer, (i.e., comprises two or more group-V species). Accordingly, materials for the sacrificial layer may include GaAsP, InGaPAs, InSbP, InSbAs, GaInSbP, GaInSbP, GaAsN, GaSbN, or combinations thereof. The sacrificial layer may additionally include aluminum along with the two or more group-V species, including, for example, AlGaSb, AlAsSb, AlSbP, or combinations thereof.

Additionally, the sacrificial layer may have a thickness of from about 10 nm to about 5 mm. In an example, the sacrificial layer may have a thickness of from about 50 nm to about 60 nm. In an example, a sacrificial layer that is lattice matched to an underlying substrate (e.g., a structure comprising an AlAsSb sacrificial layer and GaSb substrate), may have a thickness that is greater than that of a sacrificial layer that is not lattice matchined to an underlying substrate.

The active region of the embodiments may comprise at least one semiconductor and may be configured as a single layer or multiple layers. In an example, the active region comprises a quantum confined region, such as a quantum well, quantum wire, quantum dot or combinations thereof. In an example, the active region comprises a superlattice structure comprising a plurality of alternating semiconductor layers, that is, alternating p-type and n-type semiconductor layers.

The active region may comprise a type II superlattice (T2SL), for example, an Sb-based superlattice, including InAs/(In, Ga)Sb stacks. Sb-based T2SLs are currently used as absorbers in IR detectors. Thus, IR imagers will benefit from the semiconductor structures produced by practice of embodiments described herein in order to release and transfer InAs(In, GA)Sb stacks from an epitaxial growth substrate to any alternate substrate, such as from a growth substrate onto an Si substrate.

In an example, transfer of Sb-based SLs on Si will enable fabrication of IR detectors and ROICs on the same type substrate, which eliminates the large thermal mismatch between GaSb and the Si substrate. Additionally, Sb-based membranes provide for wafer-level processing of FPAs using a die-to-wafer or wafer-to-wafer bonding. Moreover, transferring Sb-based membranes to any substrate, including a flexible host, provides for fabrication of flexible IR imagers.

The active region may comprise a thickness of from about 1 nm to about 10 μm, for example from about from about 1 nm to about 10 nm (e.g., for transistors), such as from about 0.1 μm to about 2.5 μm, including from about 5 μm to a about 10 μm (e.g., for detectors/solar cells).

The protective layer can include a polymer, a dielectric and/or a metal. For example, the protective layer can comprise photoresist polymer. Accordingly, after transfer of the active region onto an alternative substrate, acetone and oxygen plasma can be used to remove the protective layer without damaging the alternate substrate. Further, the protective layer may be formed with etching holes that extend from a surface of the protective layer through a thickness thereof in order to expose at least portions of the sacrificial layer.

The alternate substrate may comprise any suitable substrate onto which a multilayer semiconductor structure may be transferred. Without any particular limitation, the alternate substrate any organic or inorganic material, and/or may be conductive or non-conductive. The alternate substrate may be a flexible or a rigid substrate. In an example, the alternate substrate may comprise a textile, polymer, silicon, germanium, or combinations thereof. The alternate substrate may be a transparent substrate. The host substrate and the alternate substrate may share some or all compositional features as one another. The alternate substrate may possess desired properties not found in the host substrate. For example, the alternate substrate may comprise Si, and may include a Si read-out circuit (ROIC) to which the active region may be bonded for forming infrared focal plane arrays.

The intermediate substrate may be used for transferring the patterned semiconductor layer from the host/growth substrate to an alternate substrate. The intermediate substrate may be utilized as a stamp which, when pressed with sufficient force against a surface of the patterned semiconductor layer, adheres to a surface thereof. For example, after the step of selectively etching the sacrificial layer and pulling the intermediate substrate away from the host substrate, the patterned semiconductor layer becomes separated from the host substrate and remains in contact with the intermediate substrate.

The intermediate substrate may include any material that is capable of sufficiently contacting a surface of the semiconductor layer such that upon exertion of sufficient pulling force away from the host substrate, the patterned semiconductor layer becomes detached from at least a portion of the selectively etched sacrificial layer. In other words, the intermediate substrate may be capable of attaching itself to the active region for the step in which the active region is pulled away from the host substrate, and may also be capable of detaching itself from the active region for the step at which the active region is stamped onto an alternate substrate.

In an example, the intermediate substrate includes polydimethylsiloxane (PDMS) (e.g., SYLGARD® 184 SILICONE ELASTOMER KIT, available from Dow Corning, Corp.), thermal tape such as that available from Semiconductor Equipment Corporation (Moorpark, Calif.), or combinations thereof. PDMS as the intermediate substrate comprises an adhesive part and a curing part. By changing the ratio of these two parts, adhesion of the PDMS can be modified and customized depending on the material and structure of the active region being removed from the host substrate and transferred to the alternate substrate. The intermediate substrate comprising PDMS may be processed after it is cured to change its adhesion properties.

### EXAMPLES

Embodiments described herein provide versatile processes to release Type II superlattices (T2SL) from their corresponding epitaxial growth substrates and transfer them to a new host so as to form Sb-based SL membranes. The processes include a wet (i.e., transfer in liquid) and dry (i.e., transfer mediated by a stamp) techniques, resulting in the transfer of T2SL membranes with thickness ranging from 100 nm to 2.5 μm, and lateral sizes going from 24×24 μm² to 1×1 cm².

Fabrication of Sb-based membranes begins with epitaxial growth of the active layer, namely the T2SL, and a sacrificial layer on a GaSb substrate. For example, InAs/GaSb T2SLs with thickness of 0.1 and 1.6 μm, and InAs/InAsSb T2SL with thickness of 2.5 μm are grown. A 60 nm Al_{0.4}Ga_{0.6}Sb film is used as sacrificial layer in all samples. Composition and thickness of the AlGaSb film are carefully selected to avoid any plastic deformation during epitaxial growth. Next, the as-grown SL membranes are released by selective removal of the Al_{0.4}Ga_{0.6}Sb film in a diluted HF solution.

As explained in more detail below, wet or dry transfer processes were utilized for transferring the SL membranes to a new host depending on the thickness and lateral size of the T2SL. A wet transfer process can be used for transfer of membranes to a new host wherein the membranes have areas as large as about 1×1 cm² and thickness in the range of from about 0.1 to about 1.6 μm. Meanwhile, a dry transfer process can be used for transfer of arrays of T2SLs from a substrate to alternative supporting material, wherein the T2SLs have lateral sizes as small as about 24×24 μm² and the substrate comprises GaSb.

### Example 1A—Epitaxial Growth

Multilayer structures including Sb-based SLs and AlGaSb sacrificial layers were grown in a VG-80 molecular beam epitaxy (MBE) reactor on n-type (Te-doped with n˜5×10¹⁷ cm⁻³) epi-ready GaSb (0 0 1). As₂ and Sb₂ valved cracker sources were used. Indium and gallium growth rates were 0.5 ML/s for Ga (which corresponds to a beam equivalent pressure (BEP) of 1.46×10⁻⁷ Torr) and 0.45 ML/s for In (which corresponds to a BEP of 2.5×10⁻⁷ Torr). Growth rates were determined by monitoring intensity oscillations in the reflected high-energy electron diffraction (RHEED) patterns. Group-V fluxes were adjusted using a conventional ion gauge to satisfy a group V/III BEP flux ratio equal to 7.5 and 3.8 for for GaSb and InAs, respectively. The substrates were initially outgassed in vacuum, and the surface oxide was removed under Sb flux at 535° C. The transition between the (1×3) and the (2×5) surface reconstruction on GaSb was observed by RHEED. The temperature corresponding to this transition was taken as a reference for all the growth temperatures.

Four different active layers were grown for this work: 1) a 100 nm T2SL, which consisted of 17 periods of 8ML InAs/8ML GaSb; 2) a 1.6 μm InAsGaSb SL including 237 periods of 8ML InAs/8ML GaSb; 3) a 2.5 μm InAs/InAsSb SL comprising 340 periods of 14ML InAs/12ML InAs_{0.81}Sb_{0.19}; 4) the p-i-n homojunction SL which consisted of 14 ML InAs/12 ML InAs_{0.81}Sb_{0.19}. The n-type layers (515 nm) were Te-doped to 2×10¹⁸ cm⁻³, while the absorber (2060 nm) and the p-type layers (158 nm) were Be-doped at 3×10¹⁶ cm⁻³ and 2×10¹⁸ cm⁻³, respectively.

### Example 1B Wet Transfer Process

Wet transfer of InAs/GaSb SLs of Example 1A to a new host was performed. A patterned photoresist or a Ti/Au coating film as protective layers were formed over the surface of the membrane superlattice membrane. Etching holes through the epitaxial layer structure and down into the substrate were defined by and a BCl₃ inductively coupled plasma (ICP) etching. The samples were intentionally over-etched all the way into the GaSb substrate, so that the Al_{0.4}Ga_{0.6}Sb film would be exposed to an etching solution during a subsequent step for releasing the membrane.

Releasing of the membrane from the host substrate was accomplished by selective etching of the Al_{0.4}Ga_{0.6}Sb sacrificial layer in a diluted HF solution ([(HF:H2O) 1:700]:ethanol 1:5). Membrane release occurred in 6 h and 16 h for samples coated with Ti/Au and photoresist, respectively. A faster membrane release in presence of metal was the result of the Ti/Au acting as a catalyst of the selective etching process. After complete removal of the AlGaSb the T2SL bonded back to the GaSb substrate. The sample was then transferred in DI water, where the membrane was observed to float off and become freestanding from the host substrate on which it was supported. An alternate substrate (e.g., a target substrate) was placed into the DI water, and the membrane adhered to it. While not limited to any particular theory, it is believed that the membrane adheres to the alternate substrate via capillary action, and that surface preparation of the alternate substrate was essential for a successful transfer. For example, as hydrophilic hosts facilitate transfer in liquid media, both the Si and Au/Ti/Si target substrates were cleaned with acetone and isopropanol, and then treated with oxygen plasma.

### Example 1C—Dry Transfer Process

For a dry transfer process, an InAs/InAsSb T2SL formed on a host substrate was patterned to form a 2D array of 24×24 μm² mesas. Spacing between the mesas was 6 μm both in the x and y directions. Membranes were patterned using a positive resist (AZ4330), and ICP etching in BCl₃. The final etch depth was 2.6 μm, i.e., higher than the epi-layer thickness, thereby allowing complete access of the etching solution to the sacrificial layer. Then, the Al_{0.4}Ga_{0.6}Sb sacrificial layer was partially etched in diluted HF and ethanol solution ([(HF:H2O) 1:700]:ethanol 1:5). After 4.5 hours, the sample was rinsed in DI water and dried with nitrogen. Partially released membranes were removed from the native growth substrate using either a PDMS stamp or thermal release tape.

The PDMS was prepared using a Sylgard 184 kit, using a known procedure. Dry transfer to the new host was accomplished by a printing process.

The new host substrate was cleaned by acetone, IPA, DI water, and through a final 2 minutes oxygen plasma treatment at 100 Watt, 0.100 Torr.

### Example 2—Surface Characterization

Residual Al_{0.4}Ga_{0.6}Sb may result in an increased roughness of the membrane backside, thereby promoting a weak bond between the transferred membrane and the new substrate. Transfer of membranes on metal-coated substrates may also be used to provide the T2SL with electrical contacts via interface bonding. In this scenario, residual Al_{0.4}Ga_{0.6}Sb could drastically increase the resistance of the contact. Therefore, to confirm that the selective etching step completely removed the sacrificial layer, the surface topography of the top and bottom surface of the released membrane were compared.

Atomic force microscopy (AFM) was used to verify that the Al_{0.4}Ga_{0.6}Sb sacrificial layer was completely removed during the release step. Structural and chemical composition of the interface between transferred membrane and alternate/new substrate were investigated via scanning transmission electron microscopy (STEM) and energy dispersive x-ray spectroscopy (EDS).

AFM was performed on an Asylum MFP-3D system in tapping mode. Scans were acquired using NSC15 cantilevers (MikroMasch) with a tip radius of 8 nm and a spring constant of 40 N/m. AFM data was analyzed by Gwyddion software. Upon using PDMS to peel the T2SL from the growth substrate after partial release of the film has occurred, the bottom surface was exposed. 2D AFM images were acquired over a 1×1 mm2 area on the front and backside of the T2SL. Root-mean-square (RMS) roughness of 0.112 nm and 0.118 nm were calculated from the AFM images. From these comparable RMS roughness values for the top and bottom surfaces of the T2SL, it was concluded that the Al_{0.4}Ga_{0.6}Sb was completely removed by the diluted HF solution, during the release step.

### Example 2B—Chemical Composition and Structural Quality Measurement

STEM and EDS were used to investigate the chemical composition and structural quality of a 2.5 μm-thick InAs/InAsSb T2SL bonded to bulk Si. Prior to membrane transfer, a Si substrate was coated with Ti/Au/Ti film. The T2SL was patterned in a 24×24 μm² pixel prior to release and dry transferred to the new host. Milling by a focused ion beam was used to obtain a thin lamella of the T2SL bonded to the Si substrate. The results ruled out the presence of voids or particles at the membrane/host interface, by showing a continuous interface bond. A high-angle annular dark field STEM (HAADF-STEM) image of the T2SL/substrate interface was also taken, where the material contrast allowed for identifying the multilayered structure of the SL and the metal coated substrate. In an EDS chemical analysis, concentration profiles for Ga, Sb, In, As, O, Ti, Au, and Si were extracted from energy dispersive spectra. The magnitudes of each elemental profile were normalized to the values obtained for Si. Intensity modulation of the STEM image allowed accurate correlation with the EDS scans through the interface. In, As, and Sb profiles showed an oscillating profile over the T2SL portion of the scan. The Au signal profile correlated with a bright its location according to the SEM image and the Ti profile had a bimodal distribution, peaking between the peaks for the Au and the superlattice, and again between the Au and the Si signal.

SEM images were taken by JEOL 5800LV system in high vacuum mode using a secondary electrons (SE) detector. A thin lamella for TEM was prepared in a FEI Q3D ESEM/FIB dual-beam system with Ga ions source. TEM characterization was performed in a JEOL 2010F high resolution TEM/Scanning-TEM with field emission e-beam accelerated at 200 kV. Chemical analysis via energy dispersive x-ray spectroscopy (EDS) was accomplished on the JEOL 2010F in STEM mode. The measurement was performed using the X-MaxN 80T, 80 mm2 detector (Oxford Instruments) with a resolution 50000 cps at 200 kV. Aztec software provided the power to acquire and process the EDS data.

While the embodiments have been illustrated respect to one or more implementations, alterations and/or modifications can be made to the illustrated examples without departing from the spirit and scope of the appended claims. In addition, while a particular feature of the embodiments may have been disclosed with respect to only one of several implementations, such feature may be combined with one or more other features of the other implementations as may be desired and advantageous for any given or particular function.

Furthermore, to the extent that the terms “including”, “includes”, “having”, “has”, “with”, or variants thereof are used in either the detailed description and the claims, such terms are intended to be inclusive in a manner similar to the term “comprising.” As used herein, the phrase “one or more of”, for example, A, B, and C means any of the following: either A, B, or C alone; or combinations of two, such as A and B, B and C, and A and C; or combinations of three A, B and C.

Other embodiments will be apparent to those skilled in the art from consideration of the specification and practice of the descriptions disclosed herein. It is intended that the specification and examples be considered as exemplary only, with a true scope and spirit of the embodiments being indicated by the following claims.

What is claimed is:

1. A method for forming a semiconductor structure, comprising:
providing a host substrate;
forming at least one sacrificial layer comprising two or more group-V species over the host substrate;
forming at least one semiconductor layer over the at least one sacrificial layer; and
transferring at least a portion of the at least one semiconductor layer from the host substrate onto an alternate substrate.

2. The method of claim 1, wherein the transferring comprises
bonding the at least one semiconductor layer to an intermediate substrate;
partially or completely releasing the at least one semiconductor layer from the host substrate;
separating the at least one semiconductor layer from the intermediate substrate; and
bonding the at least one semiconductor layer to the alternate substrate.

3. The method of claim 2, wherein the intermediate substrate comprises a stamp comprising polydimethylsiloxane (PDMS), thermal release tape, or combinations thereof.

4. The method of claim 1, further comprising selectively etching the at least one sacrificial layer.

5. The method of claim 4, wherein the selectively etching comprises dry etching, wet etching or vapor etching.

6. The method of claim 1, further comprising forming a protective layer over the at least one semiconductor layer.

7. The method of claim 6, further comprising patterning the protective layer.

8. The method of claim 1, wherein the at least one sacrificial layer comprises GaAsP, InGaPAs, InSbP, InSbAs, GaInSbP, GaInSbP, AlAsSb, AlSbP or combinations thereof.

9. The method of claim 1, wherein the at least one semiconductor layer comprises a group III-V compound semiconductor.

10. The method of claim 1, further comprising epitaxially growing the semiconductor layer on the host substrate.

11. The method of claim 1, further comprising patterning the at least one semiconductor layer to comprise a 2-dimensional (2D) array of holes, a 2D array of mesas or both.

12. The method of claim 11, wherein the patterning exposes a surface of the at least one sacrificial layer.

13. A method for forming a semiconductor structure, comprising:
providing a host substrate;
forming at least one sacrificial layer over the host substrate;
forming at least one semiconductor layer over the at least one sacrificial layer;
patterning the at least one semiconductor layer to expose sidewall portions of the semiconductor layer;
forming a protective layer over at least the exposed sidewall portions of the at least one semiconductor layer;
selectively etching the at least one sacrificial layer; and
transferring at least a portion of the at least one semiconductor layer from the host substrate onto an alternate substrate.

14. The method of claim 13, wherein the transferring comprises
bonding the at least one semiconductor layer to an intermediate substrate;
partially or completely releasing the at least one semiconductor layer from the host substrate;
separating the at least one semiconductor layer from the intermediate substrate; and
bonding the at least one semiconductor layer to the alternate substrate.

15. The method of claim 14, wherein the intermediate substrate comprises a stamp comprising polydimethylsiloxane (PDMS), thermal release tape, or combinations thereof.

16. The method of claim 13, wherein patterning the at least one semiconductor layer comprises exposing the at least one semiconductor layer to an etchant.

17. The method of claim 16, wherein the selectively etching comprises dry etching or wet etching the at least one sacrificial layer.

18. The method of claim 13, wherein the at least one sacrificial layer comprises aluminum.

19. The method of claim 13, wherein the patterning comprises etching a plurality holes through the at least one semiconductor layer, etching the at least one semiconductor layer to define a plurality of mesas, or both.

20. The method of claim 19, wherein the patterning exposes a surface of the at least one sacrificial layer.

21. The method of claim 13, wherein the at least one semiconductor layer comprises a single layer, a quantum confined region or a superlattice layer.
